(19) United States
(12) Patent Application Publication
(10) Pub. No.: US 2010/0043874 A1
(43) Pub. Date: Feb. 25, 2010

(54) NANOSTRUCTURED SOLAR CELL

(75) Inventor: Yue Liu, Plymouth, MN (US)

Correspondence Address: HONEYWELL/CST;Patent Services, 101 Columbia Road, P.O. Box 2245, Morristown, NJ, 07962-2245, US

(73) Assignee: HONEYWELL INTERNATIONAL INC., Morristown, NJ (US)

(21) Appl. No.: 11/768,690

(22) Filed: Jun. 26, 2007

(51) Int. Cl. H01L 31/00

(52) U.S. Cl. 136/256

(57) ABSTRACT

A solar cell having a nanostructure. The nanostructure may include nanowire electron conductors having a fractal structure with a relatively large surface area. The electron conductors may be loaded with nanoparticle quantum dots for absorbing photons. The dots may be immersed in a carrier or hole conductor, initially being a liquid or gel and then solidifying, for effective immersion and contact with the dots. Electrons may move flow via a load from the electron conductors to the holes of the carrier conductor. The solar cell may be fabricated, for example, with an additive process using roll-to-roll manufacturing.

### BACKGROUND

The invention pertains to electrical power devices and particularly to power generating devices. More particularly, the invention pertains to solar-based power generating devices.

### SUMMARY

The invention is a solar cell having a nano-type structure.

### BRIEF DESCRIPTION OF THE DRAWING

FIG. 1 is a diagram of a nanostructure solar cell and its operation;

FIG. 2 is an illustration of a nanostructure electron conductor of the solar cell;

FIG. 3 is a diagram of increments of a nanostructure solar cell build; and

FIG. 4 is a graph comparing the conversion efficiency of a nanostructure solar cell with that of another kind of solar cell.

### DESCRIPTION

The use of early generation solar photovoltaic (PV) technology or Si-based solar cells to generate clean electricity (as alternative to dirty fossil-fuel generated electricity) has not appeared cost competitive during the last several decades. Despite known and anticipated technology improvements and capacity increases, it still does not appear that solar cell technology will be cost competitive for electrical power generation for several more decades.

However, the present invention involving solar PV technology, based on nanostructure components and respective fabrication processes aimed to significantly increase conversion efficiency and reduce production costs, may allow a solar PV to become an economically viable form of a renewable alternative energy source within a timeframe shorter than several decades.

The present solar cell may maximize solar-to-electrical conversion efficiency through the use of nanostructure electron conductors, and nanoparticles such as quantum dots (QDs) as an absorber. The cell may be fabricated on a flexible substrate. Combining these components may result in a flexible, low-cost, rugged solar sheet which can be produced with a simple, low temperature process.

The solar cell may be a result of precise engineering of consistent QD uniformity to match solar spectra, nanowire electron conductors, matching work functions/electron affinities, efficient hole-transport media, reduction or elimination of leakage/recombination, and low temperature process compatibility.

The solar cell may include, for instance, nanowire-based electron conductors having a high surface area, significant transparency, good flexibility, and so on. The solar cell may have a QD absorber, have enhanced absorption cross-section, and have charge multiplication within the quantum dots, and be made with a simple additive process.

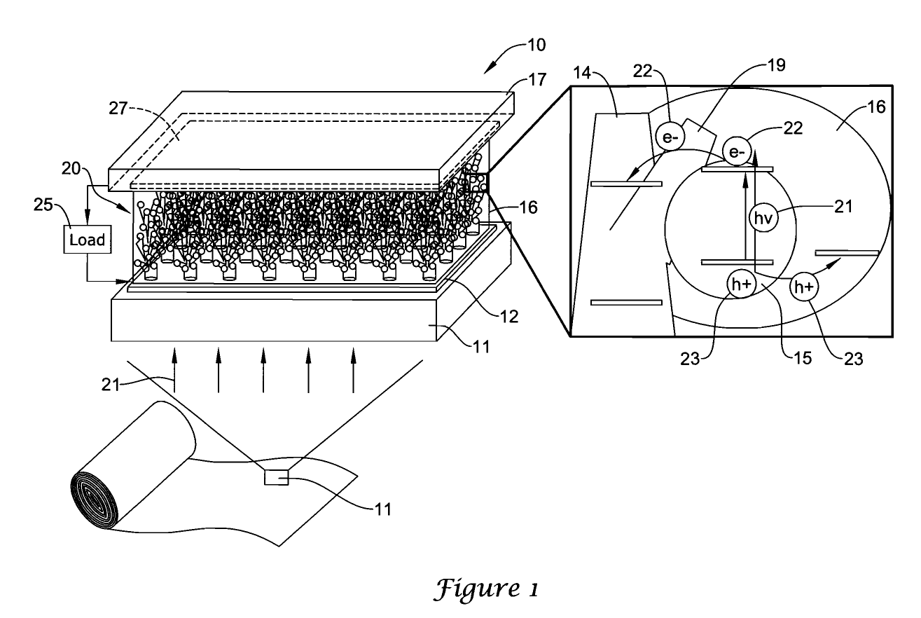

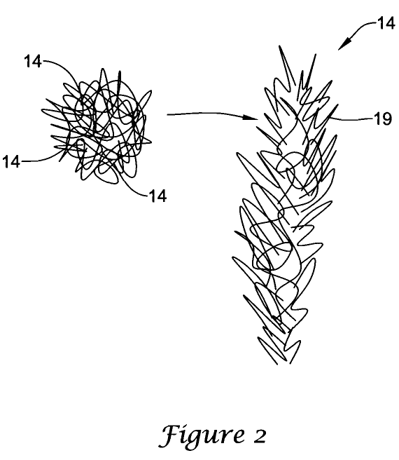

The solar cell may be a nanostructure which includes significant characteristics such as a fractal architecture of nanostructure electron conductors 14 and a solid-state hole conductor 16, as indicated in FIGS. 1 and 2. An absorber 20 may consist of quantum dots (QDs) 15 which are nanoparticles that can be shaped to be band-gap engineered so as to match a solar spectrum or spectra for optimized absorption. Band-gap engineering of the quantum dots, for a given element of material or compound, may be effected with geometrical design of the dots. Changing the shape of a quantum dot may affect the dot's band-gap. Band gaps of the QDs may be changed to maximize the solar cell's efficiency. For example, QDs may be round, oval, have points, and so on, for attaining particular energy levels to achieve particular band gaps.

QDs with enhanced absorption cross-sections may also maximize energy absorption within a very thin film, including a potential of multiple charge generation for each high-energy photon 21. Also, there may be a nanostructured high porosity electron conductors 14, which can provide maximized large surface areas for loading a solar absorber 20 of a given geometric area and thickness. The absorber elements 15 (i.e., QDs) may attach to a surface of the electron conductors 14. It may be desirable to have fractal-like architecture for nanostructured electron conductors 14 to effect an optimized charge transport within the electron conductor. The electron conductors 14 may look like trees with branches 19 to attain greater surface.

Also, there may be a complementary carrier conductor, such as a hole conductor 16, which is in intimate contact with the nanoparticles or QDs 15 which are attached to the nanoporous electron conductors 14, such that the conductor 16 provides efficient hole transfer and transport path. It is desirable to have the hole conductor 16 in a stable and solid state after completion of the solar cell fabrication. The material of the hole conductor 16 may be a polymer. These items may be formed and assembled with low-cost mass producible methods such as solution-based growth, self-assembly, additive process printing, and/or spraying, on a flexible substrate in a roll-to-roll (R2R) production line.

The present nanostructure-enabled solar cell (NESC) 10 may operate as indicated in FIG. 1. Solar energy (photons 21 with energy hν) may be absorbed by quantum dots 15, which can be engineered to maximize absorption of a spectrum). Each solar photon 21 may generate one or more pairs, each pair including an electron (e−) 22 and a hole (h+) 23. The electrons 22 may be transferred to the nanowire electron conductors 14 with structure appendages 19 consisting of a transparent electron conducting (EC) material (for example, TiO₂, ZnO, . . . ), and the electrons 22 may be collected by a transparent negative electrode (anode) 11 from a contact plate 12 on which the electron conductors 14 are situated. The holes 23 may be transferred to a transparent organic polymer hole conducting (HC) material 16 and the holes 23 may eventually be collected by a reflective and protective positive electrode (cathode) 27. The electron conducting material of conductors 14 with structures 19 should be of a certain porous nanostructure having a relatively large surface area (such that of nanowires or nanotubes 19) in order for more QDs 15 to be loaded and exposed to absorb as much solar energy as possible. FIG. 2 shows an illustration of an electron conductor 14 having nanowires or nanotubes 19. The conductor 14 may resemble a “tree” having nanowires or tubes 19 which may resemble “branches”. A group of “trees” with shorter “branches” may provide more surface area of a given volume, for holding more QDs 15.

The electron conductors 14 and hole conducting material 16 need to be in intimate contact with the QDs 15 for efficient charge transfer. The incident solar energy 21 may be considered as converted to electrical energy when the collected electrons 22 flow through an external conductive path 25 and recombine with the collected holes 23. The path 25 may be a load connected across the cathode 27 and anode 12.

An advantage of using nanowires 19 in the cell structure 10 may include the high porosity characteristic which maximizes absorber 20 loading with a resulting high absorption efficiency. Also, the fractal-type architecture of the nano electron conductors 14 with appendages of wires or tubes 19 may aid in an efficient carrier transport path and minimize carrier leakage.

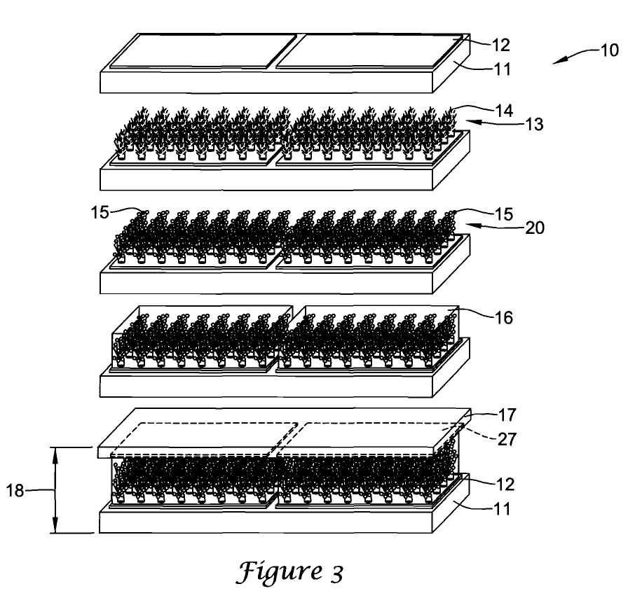

An approach for producing the present solar cell 10 may include an additive process flow with increments of the structure build as shown in FIG. 3. One may start with a flexible substrate 11. A contact layer 12 may be added and situated on substrate 11. The layer may be transparent and conductive, and be seeding for nanowires 19 of electron conductors 14. Then a layer 13 of nanowire electron conductors 14 may be added and situated on contact layer 12. The nanowires 19 may have diameters from tens to hundreds of nanometers (i.e., less than 500 nanometers) with lengths up to 20 microns. QDs 15 may be loaded to maximum levels of available space of the electron conductors and wires 14 and 19. A passivation coating (not shown) may be applied on electron conductors 14 and 19 for reduced leakage. The passivation coating may be a barrier to prevent the electrons from leaving the electron conductors 14 and recombining with holes of a hole conductor 16. Since a barrier on the QDs may prevent a desired movement of electrons or holes; a technique, for instance a chemical trick such as providing a material that permits a passage of holes but not electrons may be used. Another technique may achieve covering only open areas of the electron conductor 14 and 19 with the barrier material, and not areas of the QDs. However, if the transport of the electrons and the holes is faster than a recombination of them, then a passivation coating or barrier is not necessarily needed.

The hole+ conductor 16, may be applied in a liquid or gel form to the assembly. The liquid or gel material 16 may essentially immerse or permeate rather completely the nanoparticle CDs 15. Once applied, the liquid or gel form of the hole conductor 16 material may solidify for structural rigidity and containment. A top-reflector and contact interconnect (cathode) 27 and protective layer(s) 17 (FIG. 1) may be connected to the hole conductor 16 and added to the assembly. Layer 17 or cathode 27 may include an anti-reflective coating. Layer 17 and cathode 27 may instead be one layer. A total thickness 18 of the present solar cell 10 assembly (FIG. 3) may be less than one millimeter.

A nanostructure-enabled solar cell (NESC) 10 manufacturing process may suitably involve a low cost roll-to-roll manufacturing. The process may involve a minimum amount of and efficient use of materials, e.g., QD<1 mg/m². The desired aspects of the manufacturing or fabrication process may include a low-temperature setting and a lack of the need for a vacuum and ultra-clean environment. The present process may be compatible with using a flexible substrate 11 and a spraying/printing process for loading QDs 15 and a polymer conductor (i.e., conductor 16). The process for making the present cell 10 may leverage a manufacturing infrastructure developed for making displays (e.g., LCDs), which involves conductive transparent oxides or thin-films, and anti-reflective coatings.

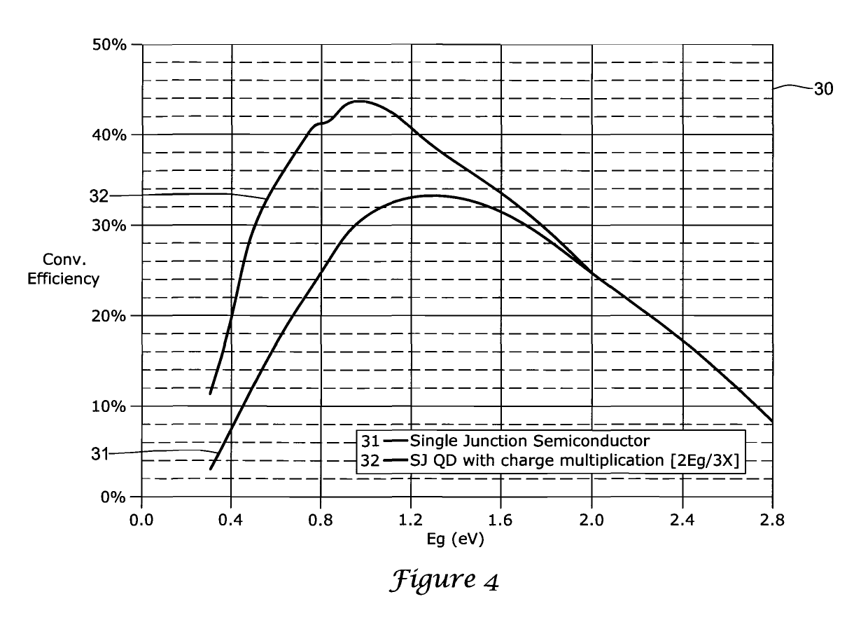

As noted herein, the use of quantum dots 15 in the cell 10 may allow bandgap engineering to match various solar spectra, provide significantly large absorption cross-sections for maximum efficiency, and result in potential charge multiplication to increase single-layer cell conversion efficiency by 30 percent as indicated by a graph 30 in FIG. 4. The graph shows conversion efficiency (percent) versus bandgap (eV) of a single junction (semiconductor) solar cell, as shown by curve 31, and of an example of the present single junction quantum dot solar cell 10 (with charge multiplication), as shown by curve 32.

The nanostructure solar cell 10 may provide relatively significant power. Solar cell 10 may have high solar-to-electrical conversion efficiency. The cell may be a flexible, light weight and highly portable energy source with a power output performance in a range of 20-40 mW/cm². Cell 10 may provide NSC 40 mW/cm² continuous power under one-sun. One cm² cell may provide adequate power for wireless communication and operation of unattended ground sensors. One to two cm² cells may power a miniature atomic-clock. Two cm² cells may power a micro gas analyzer (MGA) for one analysis every 25 seconds (with a 1 J/analysis goal). A laptop PC may be self-powered under the sun. Flexible solar sheets (of cell 10) covering a “power-helmet” may charge a cell-phone battery in less than 30 minutes.

Military applications may take advantage of the light weight of the present solar-to-electrical energy converter for soldiers' electronic field equipment (e.g., less battery and charging). The solar cell or converter 10 may provide more sustained power and longer life for unattended ground sensors compared to other like out-in-the-field power sources meeting similar power requirements. Nanostructures of the solar cell 10 may provide low cost and high efficiency for continuous power and integrated energy solutions for the soldiers' miniaturized systems.

In the present specification, some of the matter may be of a hypothetical or prophetic nature although stated in another manner or tense.

Although the invention has been described with respect to at least one illustrative example, many variations and modifications will become apparent to those skilled in the art upon reading the present specification. It is therefore the intention that the appended claims be interpreted as broadly as possible in view of the prior art to include all such variations and modifications.

What is claimed is:

1. A solar cell comprising:
an electron conductor having a nanostructure;
an absorber situated on the nanostructure; and
a hole conductor in contact with the absorber.

2. The cell of claim 1, wherein the nanostructure has a fractal structure.

3. The cell of claim 1, wherein the absorber comprises nanoparticles.

4. The cell of claim 3, wherein the nanoparticles are quantum dots.

5. The cell of claim 4, wherein the quantum dots are bandgap engineered for absorption of certain spectra of light.

6. The cell of claim 3, wherein the nanostructure is porous for providing a maximum surface area.

7. The cell of claim 1, wherein the hole conductor is a polymer.

8. The cell of claim 1, further wherein:
the nanostructure is connected to a flexible and/or transparent substrate;
the hole conductor is connected to a contact;
the substrate is an anode; and
the contact is a cathode.

9. The system of claim 1, wherein the thickness of the solar cell is less than one millimeter.

10. A method for solar-to-electrical energy conversion, comprising:
providing one or more nanoporous electron conductors;
loading the electron conductors with quantum dots to form an absorber;
providing a hole conductor in contact with the absorber; and
providing photons to the absorber; and
wherein:
the photons are absorbed by the quantum dots;
the photons generate pairs of electrons and holes;
the electrons move to the electron conductors; and
the holes move to the hole conductor.

11. The method of claim 10, further comprising:
connecting an anode to the electron conductors; and
connecting a cathode to the hole conductor; and
wherein the photons are converted to electrical energy when a conductive path is connected across the anode and the cathode such that the electrons move from the electron conductors through the load to recombine with the holes of the hole conductor.

12. The method of claim 11, wherein the path comprises at least a portion of an electronic device to be powered.

13. The method of claim 11, wherein the quantum dots are band-gap engineered to match spectra of solar light which is a source of the photons.

14. The method of claim 13, wherein an assembly comprising the anode, electron conductors, absorber, hole conductor, and cathode for solar-to-electrical energy conversion, is made with a mass production method on a flexible substrate in a roll-to-roll production process.

15. A solar energy conversion system comprising:
a first conductor;
a plurality of nanowires connected to the first conductor;
a plurality of nanoparticles loaded on the plurality of nanowires; and
a carrier conductor in contact with the nanoparticles.

16. The system of claim 15, wherein:
the nanoparticles are for absorbing photons;
each photon upon absorption breaks into an electron and a hole;
the electron goes to the nanowires; and
the hole goes to the carrier conductor.

17. The system of claim 15, wherein:
the nanowires are fabricated from transparent conducting material; and
the carrier conductor comprises a transparent organic polymer hole-conducting material.

18. The system of claim 15, wherein the nanowires have a fractal type architecture.

19. The system of claim 18, wherein the quantum dots are bandgap engineered to match spectra of solar light which is a source of the photons being absorbed.

20. The system of claim 15, wherein the system has a thickness less than one millimeter.
